(19) United States
(12) Patent Application Publication
(10) Pub. No.: US 2014/0015517 A1
(43) Pub. Date: Jan. 16, 2014

(54) POWER DETECTING APPARATUS

(71) Applicant: Atsuki IWATA, Tokyo (JP)

(72) Inventor: Atsuki IWATA, Tokyo (JP)

(21) Appl. No.: 13/932,319

(22) Filed: Jul. 1, 2013

(30) Foreign Application Priority Data
Jul. 13, 2012 (JP) 2012-157786
Jun. 11, 2013 (JP) 2013-122695

(51) Int. Cl. G01R 21/06

(52) U.S. Cl. CPC G01R 21/06
USPC 324/142

(57) ABSTRACT

A power detecting apparatus detects electrical power consumed by a load by multiplication of voltage information detected by a voltage detecting unit and current information detected by a current detecting unit. The power detecting apparatus includes: a switching unit including a single pole double throw relay that switches between a first circuit, in which a current flows through both of the voltage detecting unit and the current detecting unit, and a second circuit, in which a flow of a current to the voltage detecting unit is interrupted and a current flows through a bypass path to bypass the current detecting unit; and a control unit that performs control to switch to the first circuit when the power detection is to be performed, and control to switch to the second circuit when the power detection is not to be performed.

### CROSS-REFERENCE TO RELATED APPLICATIONS

The present application claims priority to and incorporates by reference the entire contents of Japanese Patent Application No. 2012-157786 filed in Japan on Jul. 13, 2012 and Japanese Patent Application No. 2013-122695 filed in Japan on Jun. 11, 2013.

### BACKGROUND OF THE INVENTION

1. Field of the Invention

The present invention relates to a power detecting apparatus.

2. Description of the Related Art

In recent years, with the increasing interest in energy saving, there is an increasing demand to display or provide the power consumption of equipments or devices that operate on electricity. For example, the power consumption of an air conditioner, a copier or the like is not constant but dynamically changes in various ways depending on the surrounding environment or operating modes. Therefore, there is a need to accurately detect power during operation and manage information. Furthermore, the same applies when the power consumption of an electrical equipment, a machine tool, or a home is managed or when the power consumption of a factory or the like is managed.

In the power detecting apparatus capable of detecting the power consumption of various devices that operate on electricity, it is desirable to configure a voltage detection circuit section and a current detection circuit section as low-loss sections in order to reduce the power consumption needed for power detection. If such a power detecting apparatus is employed, a detection range, detection accuracy, or detection resolution may be limited. In certain equipments or devices that operate by using a commercial alternating-current (AC) voltage as an input voltage, a method may be employed in which only a current waveform is detected while the input voltage is considered as a constant sine wave, and both of the waveforms are multiplied. However, in this method, there is a problem in that an error of synchronizing timing of both of the waveforms, an error of input voltage fluctuation, an error of waveform distortion or the like may occur and desired accuracy may not be obtained. In addition, in this case, while loss at the voltage detection section can be reduced, loss at the current detection section constantly occurs resulting in a waste.

In certain equipments or devices in which the amount of power consumption does not dynamically changes, it is possible to know the current power consumption or integral power consumption based on a power consumption value in each of predetermined operating modes, without actually performing power detection. However, there is a problem in that a detection error may occur due to the surrounding environment or a change in the input voltage.

Japanese Patent Application Laid-open No. 2002-159143 and Japanese Patent No. 3668145 are somewhat related to the present invention.

To solve the problems as described above, it is conceivable to perform control such that a current is applied to the voltage detection section and the current detection section only when the power detection is to be performed, in order to realize a power detecting apparatus that can improve detection accuracy and minimize detection loss.

However, there is a problem in that switching of these two sections in a circuit makes the circuit complicated and leads to an increase in costs and a needed space.

In view of the above circumstances, and there is a need to provide a power detecting apparatus capable of minimizing complexity of a circuit, an increase in costs, and an increase in a needed space and capable of minimizing power needed to switch a circuit.

### SUMMARY OF THE INVENTION

It is an object of the present invention to at least partially solve the problems in the conventional technology.

A power detecting apparatus includes a voltage detecting unit and a current detecting unit, and detects electrical power consumed by a load by multiplication of voltage information detected by the voltage detecting unit and current information detected by the current detecting unit. The power detecting apparatus includes: a switching unit including a single pole double throw relay that switches between a first circuit, in which a current flows through both of the voltage detecting unit and the current detecting unit to enable power detection, and a second circuit, in which a flow of a current to the voltage detecting unit is interrupted and a current flows through a bypass path to bypass the current detecting unit so as to disable the power detection; and a control unit that performs control to switch to the first circuit when the power detection is to be performed, and control to switch to the second circuit when the power detection is not to be performed.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a diagram illustrating a configuration example of a power detecting apparatus according to a first embodiment; and

FIG. 2 is a diagram illustrating a configuration example of a power detecting apparatus according to a second embodiment.

### DETAILED DESCRIPTION OF THE PREFERRED EMBODIMENTS

Embodiments of the present invention will be explained in detail below with reference to the accompanying drawings.

### First Embodiment

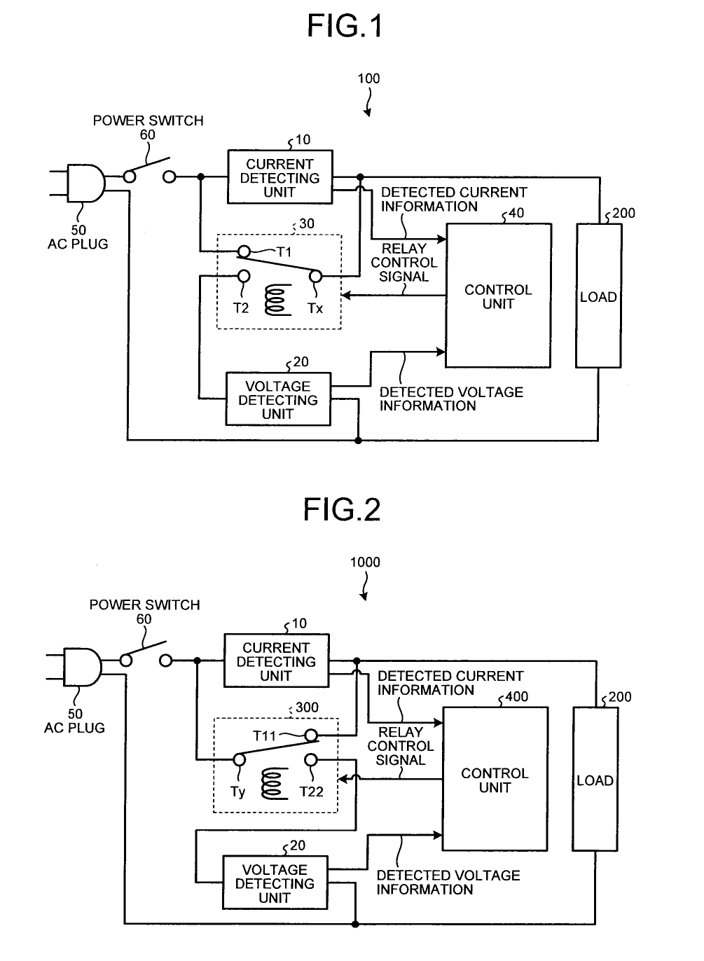

A power detecting apparatus according to the present embodiment is a power detecting apparatus that measures (detects) the electrical power of a load 200 that operates with an AC commercial power supply. FIG. 1 is a diagram illustrating a configuration example of a power detecting apparatus 100 according to the present embodiment. In the example illustrated in FIG. 1, the power detecting apparatus 100 includes at least a current detecting unit 10, a voltage detecting unit 20, a switching unit 30, and a control unit 40.

As illustrated in FIG. 1, the upper line of an AC plug 50 is connected to one terminal of a power switch 60. The other terminal of the power switch 60 is connected to one terminal of the load 200 that operates with the AC commercial power supply via the current detecting unit 10. The input (the left side in FIG. 1) and the output (the right side in FIG. 1) of the current detecting unit 10 are connected so that a current flowing through the current detecting unit 10 can be bypassed according to switching operation of the switching unit 30 that includes a single pole double throw relay. This will be explained in detail below. In the example illustrated in FIG. 1, one input side of the voltage detecting unit 20 is connected to the other terminal of the load 200 and the lower line of the AC plug 50. The switching unit 30 includes a single pole double throw relay, in which a common contact Tx is connected to the output side (right side) of the current detecting unit 10, a first contact T1 is connected to the input side (left side) of the current detecting unit 10, and a second contact T2 is connected to the other (another) input side of the voltage detecting unit 20.

As illustrated in FIG. 1, when an electrical connection between the common contact Tx and the first contact T1 is established, a second circuit is formed, in which a bypass path to bypass the current detecting unit 10 is formed and the flow of a current to the voltage detecting unit 20 is interrupted. The second circuit indicates a circuit configured such that the flow of a current to the voltage detecting unit 20 is interrupted and the current flows through the bypass path to bypass the current detecting unit 10 so as to disable the power detection.

On the other hand, when an electrical connection between the common contact Tx and the second contact T2 is established, the bypass path of the current detecting unit 10 is not formed so that the bypass current is interrupted, and the voltage detecting unit 20 and the load 200 are connected in parallel. Accordingly, a first circuit is formed, in which a connected body formed of the voltage detecting unit 20 and the load 200 connected in parallel with each other is connected to the current detecting unit 10 in series and the current flows through both of the voltage detecting unit 20 and the current detecting unit 10. The first circuit indicates a circuit configured such that the current flows through both of the current detecting unit 10 and the voltage detecting unit 20 so as to enable the power detection. In the example illustrated in FIG. 1, when the first circuit is formed, a line-to-line voltage of the AC commercial power supply can be applied to the voltage detecting unit 20. Therefore, it becomes possible to cause the current to flow through the current detecting unit 10 and apply the voltage to the voltage detecting unit 20 to activate each of the current detecting unit 10 and the voltage detecting unit 20. When the current detecting unit 10 and the voltage detecting unit 20 are activated, the current detecting unit 10 outputs detected current information and the voltage detecting unit 20 outputs detected voltage information. These pieces of the information are input to the control unit 40.

The control unit 40 can calculate the instantaneous power by multiplying a current indicated by the detected current information by a voltage indicated by the detected voltage information, based on the input detected current information and the input detected voltage information. The control unit 40 can obtain the power consumption (the electrical power of the load 200) by averaging the calculated values of the instantaneous power. The control unit 40 performs control to switch to the first circuit when the power detection is to be performed. On the other hand, the control unit 40 performs control to switch to the second circuit when the power detection is not to be performed. More specifically, when the power detection is to be performed, the control unit 40 outputs a relay control signal for establishing an electrical connection between the common contact Tx and the second contact T2 to the switching unit 30. On the other hand, when the power detection is not to be performed, the control unit 40 outputs a relay control signal for establishing an electrical connection between the common contact Tx and the first contact T1 to the switching unit 30. When the power detection is not needed, the control unit 40 can consider the power of the load 200 as constant and need not actually perform the power detection. In this case, the control unit 40 can calculate expected power during a period in which the power detection is not needed, by managing time and multiplying the above-described constant power by a predetermined time. In this way, it becomes possible to manage the power consumption. The control unit 40 includes, for example, a CPU or a DSP, and performs calculations and control processes as described above.

Regarding whether in the case of the first circuit or the second circuit, excitation should be performed (whether in either case the excitation current is caused to flow through the relay), for example, when the ratio of a power measurement time to a current-carrying time of a device system in which the power is to be measured (a current-carrying time of the load 200) is equal to or smaller than a threshold (for example, ½ or less), that is, when it is expected that the measurement time is short, a configuration is employed in which the relay is excited to form the first circuit. Namely, when it is expected that the ratio of the detection time to detect the power to the current-carrying time of the load 200 is ½ or smaller (a half or smaller), it is preferable to configure the single pole double throw relay such that an electrical connection between the common contact Tx and the second contact T2 is established when the excitation current flows (switched to the first circuit) and an electrical connection between the common contact Tx and the first contact T1 is established when the excitation current does not flow (switched to the second circuit). The control unit 40 switches to the first circuit by causing the excitation current to flow through the single pole double throw relay when the power detection is to be performed, and switches to the second circuit by stopping the supply of the excitation current to the single pole double throw relay when the power detection is not to be performed.

When the ratio of the power measurement time to the current-carrying time of the device system in which the power is to be measured (the current-carrying time of the load 200) is greater than the threshold (for example, greater than ½), that is, when it is expected that the measurement time is long, a configuration is employed in which the relay is excited to form the second circuit. Namely, when it is expected that the ratio of the detection time to detect the power to the current-carrying time of the load 200 is greater than ½, it is preferable to configure the single pole double throw relay such that an electrical connection between the common contact Tx and the first contact T1 is established when the excitation current flows (switched to the second circuit) and an electrical connection between the common contact Tx and the second contact T2 is established when the excitation current does not flow (switched to the first circuit). The control unit 40 switches to the second circuit by stopping the supply of the excitation current to the single pole double throw relay when the power detection is to be performed, and switches to the first circuit by causing the excitation current to flow through the single pole double throw relay when the power detection is not to be performed.

With the above configuration, it is possible to minimize loss at the current detecting unit 10 and the voltage detecting unit 20. Meanwhile, when it is expected that the ratio of the power measurement time to the current-carrying time of the device system in which the power is to be measured is equal to a half (½), a configuration may be employed in which the relay is excited to form the first circuit or a configuration may be employed in which the relay is excited to form the second circuit. The expected amount of loss is the same between the both cases.

Furthermore, if the single pole double throw relay is configured as a latching relay, in which the circuit condition is switched by causing a pulse current to flow only when the circuit condition is to be switched, it becomes possible to further reduce loss.

As explained above, according to the present embodiment, the switching unit 30 includes the single pole double throw relay that can switch between the first circuit, in which the current flows through both of the voltage detecting unit 20 and the current detecting unit 10 so as to enable the power detection, and the second circuit, in which the flow of a current to the voltage detecting unit 20 is interrupted and the current flows through the bypass path to bypass the current detecting unit 10 so as to disable the power detection. In addition, the control unit 40 performs control to switch to the first circuit when the power detection is to be performed, and performs control to switch to the second circuit when the power detection is not to be performed. Namely, depending on whether the power detection is to be performed, switching between the circuit connection to the voltage detecting unit 20 (the current flows through the voltage detecting unit 20) and the circuit disconnection from the voltage detecting unit 20 (the current does not flow through the voltage detecting unit 20) and switching between a bypass open condition of the current detecting unit 10 (the state in which the current flows through the current detecting unit 10) and a bypass shorted condition (the state in which the current flows through the bypass path without flowing through the current detecting unit 10) can be realized only by the switching operation of the single pole double throw relay. Therefore, it is possible to minimize complexity of the circuit, an increase in costs, and an increase in a needed space, and it is also possible to minimize the electrical power needed to switch between circuit conditions.

In the power detecting apparatus 100 illustrated in FIG. 1 as explained above, the current detecting unit 10 detects electrical current flowing through the load 200 and the electrical current flowing through the voltage detecting unit 20 (loss at the voltage detecting unit 20), and the voltage detecting unit 20 detects only the voltage applied to the load. A slight error occurs from the entire power consumption of the system including the loss at the current detecting unit 10 and the voltage detecting unit 20 related to the power detection. The error can be corrected by taking into account the voltage drop in the current detecting unit 10. However, if the value of the current flowing through the load 200 is relatively small, the voltage drop in the current detecting unit 10 is also small, so that the error can be ignored. Therefore, the configuration of the power detecting apparatus 100 illustrated in FIG. 1 by way of example is suitable for the power detection when the value of the current flowing through the load 200 is relatively small.

### Second Embodiment

A second embodiment will be explained below. The same components as those of the first embodiment described above are denoted by the same reference numerals and symbols, and explanation thereof will be omitted appropriately. FIG. 2 is a diagram illustrating a configuration example of a power detecting apparatus 1000 according to the second embodiment.

For example, when the value of the current flowing through the load 200 is relatively large, the voltage drop in the current detecting unit 10 becomes relatively large, so that the influence of the voltage value (the voltage drop value in the current detecting unit 10) is not ignorable. Therefore, in this case, a configuration as illustrated in FIG. 2 is preferable. Specifically, the current detecting unit 10 detects only the current flowing through the load 200 and the voltage detecting unit 20 detects a total voltage value of the voltage applied to the load 200 and the voltage drop in the current detecting unit 10 in the configuration. In the power detection of this case, the current detecting unit 10 cannot detect the current flowing through the voltage detecting unit 20 (the amount of loss at the voltage detecting unit 20). Therefore, it is needed to sufficiently reduce the current flowing through the voltage detecting unit 20 (the amount of loss at the voltage detecting unit 20). The power detecting apparatus 1000 in this configuration as illustrated in FIG. 2 is suitable for the power detection when the value of the current flowing through the load 200 is relatively large.

A detailed configuration of the power detecting apparatus 1000 according to the second embodiment will be explained below. As illustrated in FIG. 2, the upper line of the AC plug 50 is connected to one terminal of the power switch 60. The other terminal of the power switch 60 is connected to one terminal of the load 200 that operates with the AC commercial power supply, via the current detecting unit 10. The input (the left side in FIG. 2) and the output (the right side in FIG. 2) of the current detecting unit 10 are connected so that a current flowing through the current detecting unit 10 can be bypassed according to switching operation of a switching unit 300 that includes a single pole double throw relay. This will be explained in detail below. In the example illustrated in FIG. 2, one input side of the voltage detecting unit 20 is connected to the other terminal of the load 200 and the lower line of the AC plug 50. The switching unit 300 includes a single pole double throw relay, in which a common contact Ty is connected to the input side (left side) of the current detecting unit 10, a first contact T11 is connected to the output side (the right side) of the current detecting unit 10, and a second contact T22 is connected to the other (another) input side of the voltage detecting unit 20.

As illustrated in FIG. 2, when an electrical connection between the common contact Ty and the first contact T11 is established, the second circuit is formed, in which a bypass path to bypass the current detecting unit 10 is formed and the flow of a current to the voltage detecting unit 20 is interrupted. On the other hand, when an electrical connection between the common contact Ty and the second contact T22 is established, the bypass path of the current detecting unit 10 is not formed such that the bypass current is interrupted, and the current detecting unit 10 and the load 200 are connected in series. Accordingly, a first circuit is formed, in which a connected body formed of the current detecting unit 10 and the load 200 connected in series with each other is connected to the voltage detecting unit 20 in parallel and the current flows through both of the voltage detecting unit 20 and the current detecting unit 10.

When the power detection is to be performed, a control unit 400 according to the second embodiment outputs a relay control signal for establishing an electrical connection between the common contact Ty and the second contact T22 to the switching unit 300. On the other hand, when the power detection is not to be performed, the control unit 400 outputs a relay control signal for establishing an electrical connection between the common contact Ty and the first contact T11 to the switching unit 300.

Modifications

While the embodiments of the present invention have been explained above, the present invention is not limited to the embodiments described above, and may be modified in various forms within the scope of the gist of the present invention. In other words, it is sufficient that the power detecting apparatus of the present invention includes a switching unit (for example, the switching unit 30 or 300 described above) and a control unit (for example, the control unit 40 or 400 described above). The switching unit includes a single pole double throw relay that can switch between the first circuit, in which the current flows through both of the voltage detecting unit 20 and the current detecting unit 10 so as to enable the power detection, and the second circuit, in which the flow of a current to the voltage detecting unit 20 is interrupted and the current flows through the bypass path to bypass the current detecting unit 10 so as to disable the power detection. The control unit performs control to switch to the first circuit when the power detection is to be performed, and performs control to switch to the second circuit when the power detection is not to be performed.

Furthermore, for example, the power detecting apparatus (100 or 1000) of the above embodiments may be mounted and applied to various devices, equipments, or systems.

For example, when an image forming apparatus has various mode states, such as an OFF mode, a power saving mode, a standby mode, and an operating mode, and when the power consumption changes according to the use condition or the surrounding environment condition in the standby mode and the operating mode, the power detecting apparatus according to the present invention may be mounted to detect the power in the standby mode and the operating mode. In the OFF mode and the power saving mode, in which the power consumption can be considered as constant regardless of the use condition and the surrounding environment condition, it is preferable not to perform the power detection to reduce loss at this time while managing the value of the power at this time as a constant value.

Furthermore, for example, the power detecting apparatus according to the present invention may be mounted on an electrical equipment, such as an electrical rice-cooker, a thermostatic cooker, or a refrigerator. In the electrical rice-cooker or the thermostatic cooker, the power consumption in the standby state can be considered as constant, but the power consumption dynamically changes in the heating operation or the heat-retention operation depending on a heat-up state, a temperature state, or a heat-retention state of ingredients being cooked. In addition, the power is influenced by the atmosphere temperature. Therefore, it is preferable to perform the power detection in the heating operation or the heat-retention operation, and not to perform the power detection in the standby state to reduce loss at this time while managing the value of the power at this time as a constant value. Regarding the refrigerator or the like, the power consumption during night time in which the door of the refrigerator may not be opened and closed can be considered as constant, and the power consumption changes during other time because the door is opened and closed to store or remove food in or from the refrigerator. Therefore, regarding the refrigerator or the like, it is preferable to divide the time into parts such that detection of the power consumption is performed in one part and is not performed in the other part, and not to perform the power detection during night time to reduce loss at this time while managing the value of the power consumption at this time as a constant value, but to perform the power detection during time other than the night time.

Moreover, for example, the power detecting apparatus according to the present invention may be mounted on an air-conditioning equipment. In the air-conditioning equipment, the power consumption in the standby state (when the operation is stopped) can be considered as constant, but the power consumption changes during operation (when the air conditioning is controlled at an appropriate temperature) depending on the temperature distribution in a room or a space, an ambient temperature, or the number of people. Therefore, it is preferable to perform the power detection during operation, but not to perform the power detection in the standby state to reduce loss at this time while managing the value of the power consumption as a constant value.

Furthermore, for example, the power detecting apparatus according to the present invention may be mounted on a machine tool. In the machine tool, the power consumption in the standby state (when the operation is stopped) can be considered as constant, but the power consumption changes during operation depending on the quality or the size of a material to be machined, cut, or polished, the condition of a lubricant, or the like. Therefore, it is preferable to perform the power detection during operation, but not to perform the power detection in the standby state to reduce loss at this time while managing the value of the power consumption as a constant value.

Moreover, the power detecting apparatus according to the present invention may be applied to a production management system for a production line in a manufacturing factory. In the production line, various devices are operated while the line is in operation, and the power consumption is changing. If the supply of power to the line is not stopped and a temporary standby state is established during lunch break or recess time, the power consumption can be considered as constant. Therefore, it is preferable to perform the power detection when the line is in operation, but not to perform the power detection in the temporary standby state during lunch break, break time, or the like to reduce loss at this time while managing the value of the power consumption as a constant value.

Furthermore, for example, the power detecting apparatus according to the present invention may be applied to a house wiring to manage the power consumption. As a system that detects all power consumption in each home, it is preferable to divide the time into parts such that detection of the power is performed in one part but is not performed in the other part, similarly to the case of the refrigerator as described above. Specifically, it is assumed that the power consumption is constant during night time but the power consumption changes during other time (wake-up time in the morning to bedtime). It is preferable not to perform the power detection during night time to reduce loss at this time while managing the value of the power as a constant value, but to perform the power detection during time other than the night time.

The embodiments and modifications as described above may be combined appropriately. As described above, according to one embodiment of the present invention, it is possible to switch between the first circuit and the second circuit by only the switching operation of the single pole double throw relay depending on whether the power detection is to be performed. Therefore, it is possible to provide a power detecting apparatus that does not cause complexity of circuits, an increase in costs, and an increase in a needed space. Furthermore, if a latching relay is employed as the relay, it becomes possible to provide the power detecting apparatus that can minimize the power needed to switch the circuit. Moreover, it is possible to provide an image forming apparatus, an electrical equipment, an air-conditioning equipment, a machine tool, a production management system, or a house wiring, that has good power saving capability and that can manage the power consumption by applying such a power detecting apparatus.

According to one embodiment of the present invention, it is possible to minimize complexity of the circuit, an increase in costs, and an increase in a needed space, as well as to minimize the power needed to switch the circuit.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A power detecting apparatus that includes a voltage detecting unit and a current detecting unit, and that detects electrical power consumed by a load by multiplication of voltage information detected by the voltage detecting unit and current information detected by the current detecting unit, the power detecting apparatus comprising:
a switching unit including a single pole double throw relay that switches between a first circuit, in which a current flows through both of the voltage detecting unit and the current detecting unit to enable power detection, and a second circuit, in which a flow of a current to the voltage detecting unit is interrupted and a current flows through a bypass path to bypass the current detecting unit so as to disable the power detection; and
a control unit that performs control to switch to the first circuit when the power detection is to be performed, and control to switch to the second circuit when the power detection is not to be performed.

2. The power detecting apparatus according to claim 1, wherein
an output side of the current detecting unit is connected to one terminal of the load,
one input side of the voltage detecting unit is connected to the other terminal of the load, and
the single pole double throw relay is configured such that
a common contact is connected to an output side of the current detecting unit,
a first contact is connected to an input side of the current detecting unit, and
a second contact is connected to another input side of the voltage detecting unit,
when an electrical connection between the common contact and the first contact is established, the second circuit is formed, in which the bypass path is formed and a flow of a current to the voltage detecting unit is interrupted, and
when an electrical connection between the common contact and the second contact is established, the first circuit is formed, in which a connected body formed of the voltage detecting unit and the load connected in parallel, with each other is connected to the current detecting unit in series and a current flows through both of the voltage detecting unit and the current detecting unit to enable the power detection.

3. The power detecting apparatus according to claim 1, wherein
an output side of the current detecting unit is connected to one terminal of the load,
one input side of the voltage detecting unit is connected to the other terminal of the load,
the single pole double throw relay is configured such that,
a common contact is connected to an input side of the current detecting unit,
a first contact is connected to an output side of the current detecting unit,
a second contact is connected to another input side of the voltage detecting unit,
when an electrical connection between the common contact and the first contact is established, the second circuit is formed, in which the bypass path is formed and a flow of a current to the voltage detecting unit is interrupted, and
when an electrical connection between the common contact and the second contact is established, the first circuit is formed, in which a connected body formed of the current detecting unit and the load connected in series with each other is connected to the voltage detecting unit in parallel and a current flows through both of the voltage detecting unit and the current detecting unit.

4. The power detecting apparatus according to claim 2, wherein when it is expected that a ratio of a detection time during which the power detection is performed to a current-carrying time of the load becomes equal to or smaller than a threshold, the single pole double throw relay is configured such that an electrical connection between the common contact and the second contact is established when an excitation current flows, and an electrical connection between the common contact and the first contact is established when the excitation current does not flow, and
the control unit performs control to cause the excitation current to flow through the single pole double throw relay when the power detection is to be performed, and control to stop supply of the excitation current to the single pole double throw relay when the power detection is not to be performed.

5. The power detecting apparatus according to claim 3, wherein when it is expected that a ratio of a detection time during which the power detection is performed to a current-carrying time of the load becomes equal to or smaller than a threshold, the single pole double throw relay is configured such that an electrical connection between the common contact and the second contact is established when an excitation current flows, and an electrical connection between the common contact and the first contact is established when the excitation current does not flow, and
the control unit performs control to cause the excitation current to flow through the single pole double throw relay when the power detection is to be performed, and control to stop supply of the excitation current to the single pole double throw relay when the power detection is not to be performed.

6. The power detecting apparatus according to claim 2, wherein when it is expected that a ratio of a detection time during which the power detection is performed to a current-carrying time of the load becomes greater than a threshold, the single pole double throw relay is configured such that an electrical connection between the common contact and the first contact is established when an excitation current flows, and an electrical connection between the common contact and the second contact is established when the excitation current does not flow, and
the control unit performs control to stop supply of the excitation current to the single pole double throw relay when the power detection is to be performed, and control to cause the excitation current to flow through the single pole double throw relay when the power detection is not to be performed.

7. The power detecting apparatus according to claim 3, wherein when it is expected that a ratio of a detection time during which the power detection is performed to a current-carrying time of the load becomes greater than a threshold, the single pole double throw relay is configured such that an electrical connection between the common contact and the first contact is established when an excitation current flows, and an electrical connection between the common contact and the second contact is established when the excitation current does not flow, and
the control unit performs control to stop supply of the excitation current to the single pole double throw relay when the power detection is to be performed, and control to cause the excitation current to flow through the single pole double throw relay when the power detection is not to be performed.

8. The power detecting apparatus according to claim 2, wherein the single pole double throw relay is a latching relay.

9. The power detecting apparatus according to claim 3, wherein the single pole double throw relay is a latching relay.

10. An image forming apparatus comprising the power detecting apparatus according to claim 1.

11. An electrical equipment comprising the power detecting apparatus according to claim 1.

12. An air-conditioning equipment comprising the power detecting apparatus according to claim 1.

13. A machine tool comprising the power detecting apparatus according to claim 1.

14. A production management system comprising the power detecting apparatus according to claim 1.

15. A house wiring comprising the power detecting apparatus according to claim 1.
